(19) United States
(12) Patent Application Publication
(10) Pub. No.: US 2026/0090128 A1
(43) Pub. Date: Mar. 26, 2026

(54) IMAGE SENSOR

(71) Applicant: Samsung Electronics Co., Ltd., Suwon-si (KR)

(72) Inventors: Sang-Hoon Song, Suwon-si (KR); Taemin Kim, Suwon-si (KR); Seungkuk Kang, Suwon-si (KR); Hongki Kim, Suwon-si (KR); Hoonil Yang, Suwon-si (KR)

(21) Appl. No.: 19/238,641

(22) Filed: Jun. 16, 2025

(30) Foreign Application Priority Data
Sep. 25, 2024 (KR) 10-2024-0129951

(51) Int. Cl. H10F 39/00

(52) U.S. Cl. CPC H10F 39/811; H10F 39/018; H10F 39/809

(57) ABSTRACT

An image sensor includes a first chip including a first substrate having a sensing region and a pad region and opposing first and second surfaces, a first interlayer insulating layer on the first surface of the first substrate and having first wiring patterns therein, and color filters on the second surface of the first substrate. The image sensor further includes a second chip on the first surface of the first substrate. The first chip includes, in the pad region, a pad contact pattern, a connection electrode electrically connected to the pad contact, and a connection contact structure electrically connected to the connection electrode. The first wiring patterns include a connection wiring pattern that is nearest to the first surface, and the connection contact structure is electrically connected to the connection wiring pattern.

### CROSS-REFERENCE TO RELATED APPLICATIONS

This U.S. non-provisional patent application claims priority under 35 U.S.C. § 119 of Korean Patent Application No. 10-2024-0129951, filed on Sep. 25, 2024, the entire contents of which are hereby incorporated by reference.

### TECHNICAL FIELD

The present disclosure herein relates to an image sensor.

### BACKGROUND

An image sensor is a semiconductor device that converts an optical image to an electrical signal. The image sensor may be classified into a charge coupled device (CCD) type and a complementary metal oxide semiconductor (CMOS) type. The CMOS type image sensor is also referred to as a CMOS image sensor (CIS). The CIS includes a plurality of pixels. The pixels may include photodiodes (PD) two-dimensionally arranged. The photodiode is configured to convert incident light into electrical signals.

### SUMMARY

The present disclosure provides an image sensor in which yield reduction caused by damage to a connection wiring pattern is improved.

Advantages of the inventive concepts are not limited to those mentioned above, and other advantages that are not explicitly mentioned may be clearly understood from description below by those skilled in the art.

An embodiment of the inventive concept provides an image sensor including a first chip including a first substrate including a sensing region and a pad region and opposing first and second surfaces, a first interlayer insulating layer on the first surface of the first substrate and having first wiring patterns therein, and color filters on a second surface of the first substrate. The image sensor further includes a second chip provided on the first surface of the first substrate. The first chip includes, in the pad region, a pad contact pattern, a connection electrode electrically connected to the pad contact pattern, and a connection contact structure electrically connected to the connection electrode. The first wiring patterns include a connection wiring pattern that is nearest to the first surface, and the connection contact structure is electrically connected to the connection wiring pattern.

In an embodiment of the inventive concept, an image sensor includes a first chip including a first substrate including a sensing region and a pad region and first and second opposing surfaces, a first interlayer insulating layer on the first surface of the first substrate and having first wiring patterns therein, and color filters on a second surface of the first substrate. The image sensor further includes a second chip on the first surface of the first substrate. The first chip includes, in the pad region, a pad contact pattern, a connection electrode electrically connected to the pad contact pattern, and a connection contact structure electrically connected to the connection electrode, and in the sensing region, active contact plugs connected to active regions of the first substrate, and the active contact plugs and the connection contact structure are at a same level of the first interlayer insulating layer relative to the first surface of the first substrate, and have respective shapes that are tapered toward the first surface.

In an embodiment of the inventive concept, an image sensor includes a first chip including a sensing region, a pad region, and an optically black region between the sensing region and the pad region, and a second chip provided on one surface of the first chip, and including circuits configured for driving the first chip. The first chip includes a first substrate having opposing first and second surfaces, transfer gates on the first surface of the first substrate, an element isolation portion in the first substrate, a rear surface insulating layer on the second surface of the first substrate, photoelectric conversion portions spaced apart from each other with the element isolation portion therebetween, a first interlayer insulating layer between the first substrate and the second chip, and first wiring patterns in the first interlayer insulating layer. The second chip includes a second substrate, a second interlayer insulating layer, and second wiring patterns in the second interlayer insulating layer on the second substrate. The first chip further includes, in the pad region, a pad contact pattern, a connection electrode electrically connected to the pad contact pattern, and a connection contact structure electrically connected to the connection electrode. The first wiring patterns include a connection wiring pattern that is nearest to the first surface, and the connection contact structure is electrically connected to the connection wiring pattern.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a plan view of an image sensor according to embodiments of the inventive concepts;

FIG. 2 is an enlarged view of region P of FIG. 1;

FIG. 3 is a cross-sectional view taken along line A-A′ of FIG. 1;

FIG. 4 is an enlarged view of region Q of FIG. 3;

FIGS. 5, 6, 7, and 8 are enlarged views of region U of FIG. 4;

FIGS. 9, 10, and 11 are plan views of a connection contact structure and a connection electrode;

FIGS. 12, 13, 14, 15, 16, and 17 are diagrams sequentially illustrating a method for manufacturing an image sensor according to embodiments of the inventive concepts, and are cross-sectional views taken along line A-A′ of FIG. 1; and

FIG. 18 is a cross-sectional view of an image sensor according to embodiments of the inventive concepts, and is a cross-sectional view taken along line A-A′ of FIG. 1.

### DETAILED DESCRIPTION OF EMBODIMENTS

Hereinafter, embodiments of the inventive concept will be described with reference to the accompanying drawings in more detail in order to more specifically describe the inventive concepts. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

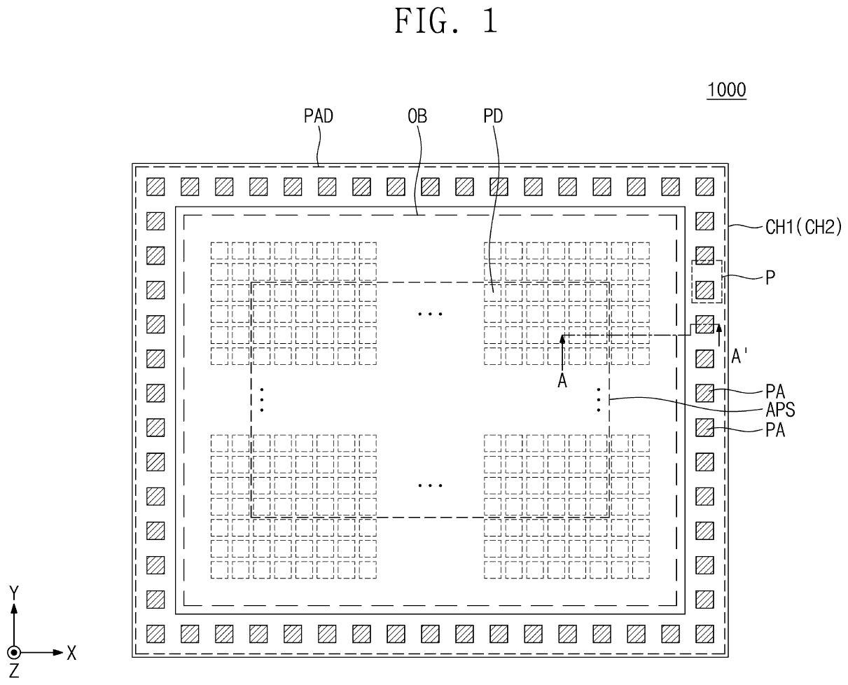

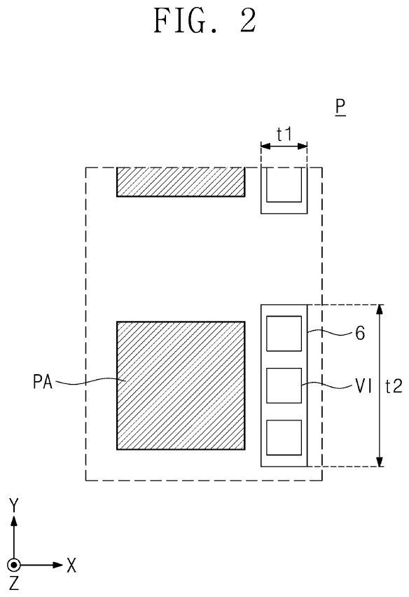

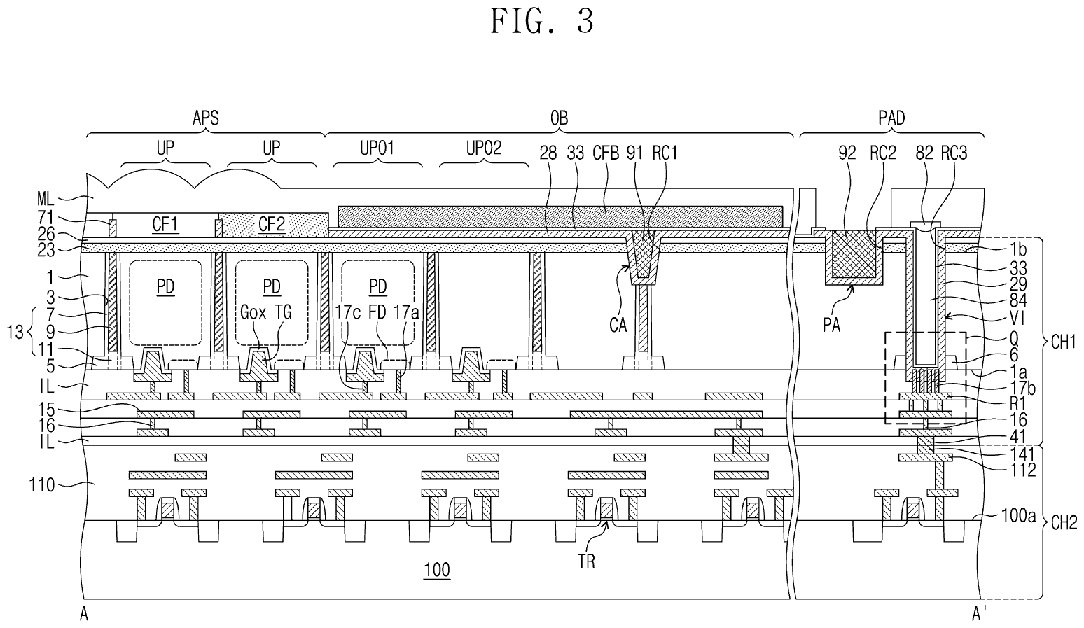

FIG. 1 is a plan view of an image sensor according to embodiments of the inventive concept. FIG. 2 is an enlarged view of region P of FIG. 1. FIG. 3 is a cross-sectional view taken along line A-A′ of FIG. 1.

Referring to FIGS. 1 to 3, an image sensor 1000 according to the present embodiment may have a structure in which a first chip CH1 and a second chip CH2 are stacked and bonded. The first chip CH1 may have an image-sensing function. The second chip CH2 may include circuits for driving the first chip CH1, or processing and storing an electrical signal generated by the first chip CH1.

The second chip CH2 may include a second substrate 100, a plurality of transistors TR disposed on a first surface 100a of the second substrate 100, a second interlayer insulating layer 110 covering the second substrate 100, and second wiring patterns 112 disposed in the second interlayer insulating layer 110. For example, the second substrate 100 may be a silicon single-crystalline substrate, a silicon epitaxial layer, or a silicon-on-insulator (SOI) substrate. The second interlayer insulating layer 110 may have a structure of a single layer of at least one of a silicon oxide layer, a silicon nitride layer, a silicon oxynitride layer or a porous insulating layer, or a structure including multiple layers thereof.

The first chip CH1 includes a first substrate 1 including a pad region PAD, an optically black region OB and a sensing region APS. The optically black region OB and the pad region PAD may be disposed on at least one side of the sensing region APS. For example, the optically black region OB and the pad region PAD may each surround the sensing region APS. The optically black region OB may be disposed between the pad region PAD and the sensing region APS. The first substrate 1 includes a first surface 1a and a second surface 1b. For example, the first substrate 1 may be a silicon single-crystalline substrate, a silicon epitaxial layer, or a silicon-on-insulator (SOI) substrate. The first substrate 1 may be doped with a first conductive-type impurity. For example, the first conductive-type may be a P-type.

The sensing region APS may include a plurality of photoelectric conversion portions PD two-dimensionally disposed along a first direction X and a second direction Y. The photoelectric conversion portions PD may be isolated from each other by disposing an element isolation portion 13 in the sensing region APS of the first substrate 1. Hereinafter, a region isolated by the element isolation portion 13 is defined as a light receiving region UP. The photoelectric conversion portion PD may be disposed in not only the sensing region APS but also the optically black region OB in the first substrate 1. For example, the photoelectric conversion portion PD may be doped with a second conductive-type impurity opposite to the first conductive-type impurity. For example, the second conductive-type may be an N-type. An N-type impurity region formed by doping the photoelectric conversion portion PD may form a PN junction with a P-type impurity region of the substrate 1 adjacent thereto to provide a photodiode.

The element isolation portion 13 may extend to the optically black region OB. In the sensing region APS, a first element isolation layer 5 may be disposed adjacent to the first surface 1a of the first substrate 1. The element isolation portion 13 may penetrate the first element isolation layer 5. The element isolation portion 13 may include a conductive pattern 9 disposed in a trench 3, an isolation insulating layer 7 surrounding a side surface of the conductive pattern 9 and a buried insulating pattern 11 interposed between the conductive pattern 9 and the first surface 1a of the first substrate 1. The conductive pattern 9 may include a conductive material, for example, metal or impurity-doped polysilicon. For example, the isolation insulating layer 7 may include a silicon oxide layer. For example, the buried insulating patterns 11 may include a silicon oxide layer.

The first element isolation layer 5 may include a silicon oxide layer inserted or extending from the first surface 1a of the first substrate 1 into the inside thereof. For example, the first element isolation layer 5 may include a silicon nitride layer interposed between silicon oxide layers.

It is illustrated that there is a boundary between the first element isolation layer 5 and the element isolation portion 13, but the boundary between the first element isolation layer 5 and the element isolation portion 13 may not be inspected (e.g., may not be visible). For example, there may not be an interface between the first element isolation layer 5 and the isolation insulating layer 7. In addition, an interface between the isolation insulating layer 7 and the buried insulating pattern 11 may not be visible or otherwise inspected.

A transfer gate TG may be disposed on the first surface 1a of the first substrate 1. For example, a first part of the transfer gate TG may be provided in the first surface 1a of the first substrate 1, and a second part may be provided on the first surface 1a of the first substrate 1. That is, the transfer gate TG may partially extend into the first substrate 1. The transfer gate TG may be a gate electrode of a transfer transistor.

A gate insulating layer Gox may be interposed between the transfer gate TG and the first substrate 1. A floating diffusion region FD may be disposed on one side of the transfer gate TG in the first substrate 1. For example, the floating diffusion region FD may be a region doped with the second conductive-type impurity.

Light may be incident into the first substrate 1 through the second surface 1b of the first substrate 1. That is, the image sensor 1000 may be a backside-illuminated image sensor. Pairs of electron-holes may be generated in the PN junction by the incident light. A voltage may be applied to the transfer gate TG to move electrons to the floating diffusion region FD.

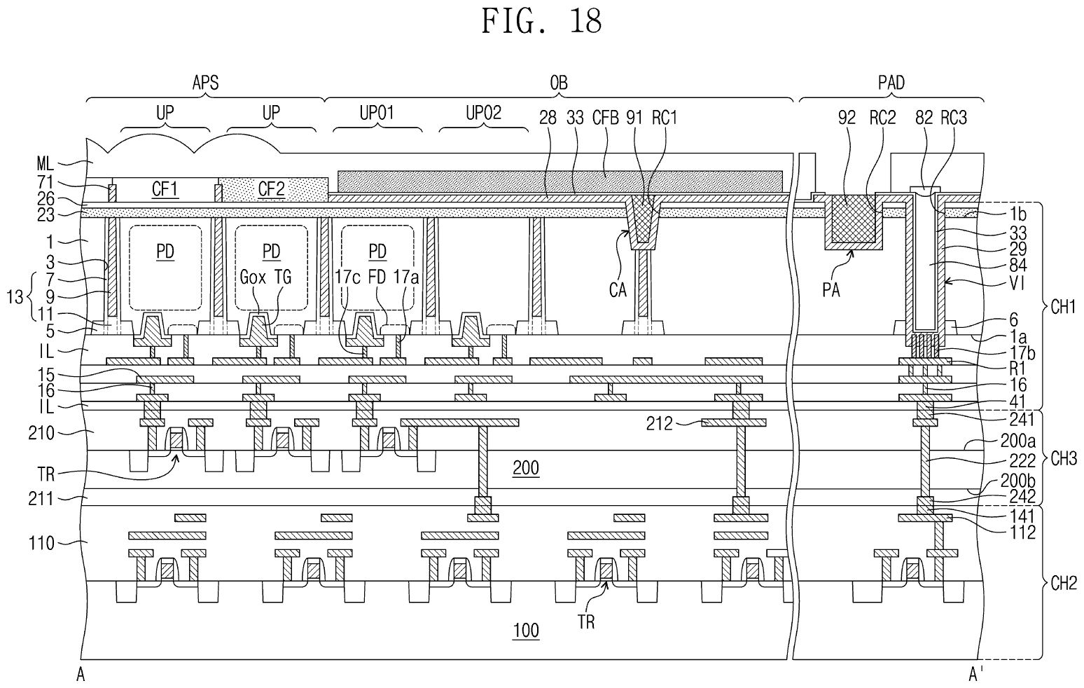

In addition to the photoelectric conversion portion PD and the transfer gate TG, a gate electrode of a reset transistor, a gate electrode of a source follower transistor, and a gate electrode of a selection transistor which are not illustrated may be provided on the first surface 1a of the first substrate 1. The photoelectric conversion portion PD and the transistors may constitute a unit pixel. Alternatively, the gate electrode of the reset transistor, the gate electrode of the source follower transistor, and the gate electrode of the selection transistor may be provided on a separate substrate, not the first substrate 1, as in a structure (see FIG. 18) to be described later.

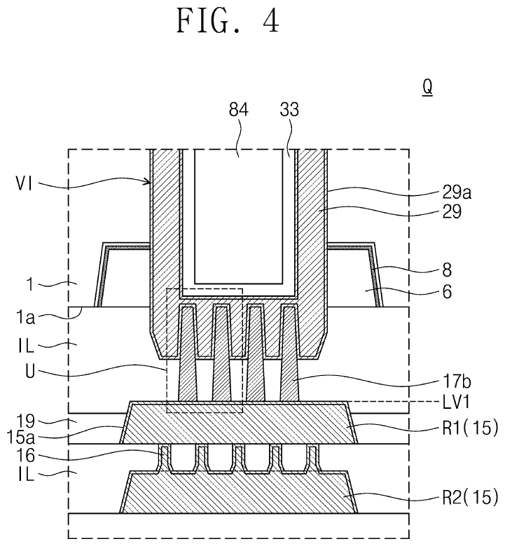

The first surface 1a of the first substrate 1 may be covered by a first interlayer insulating layer IL. The term “cover” or “surround” or “fill” as may be used herein may not require completely covering or surrounding or filling the described elements or layers, but may, for example, refer to partially covering or surrounding or filling the described elements or layers, for example, with one or more discontinuities throughout. The first interlayer insulating layer IL and the second interlayer insulating layer 110 may be in contact with each other. The first interlayer insulating layer IL may be formed of multiple layers (e.g., a multi-layer structure) including at least one of a silicon oxide layer, a silicon nitride layer, a silicon oxynitride layer or a porous low-dielectric layer. First wiring patterns 15 may be disposed inside the first interlayer insulating layer IL. For example, first wiring patterns 15 may include metal such as copper. The first wiring patterns 15 may be connected to each other by inner contact plugs 16 disposed in the first interlayer insulating layer IL. The first wiring patterns 15 and the inner contact plugs 16 may further include a barrier layer 15a (see FIG. 4) including a conductive metal nitride such as titanium nitride, tantalum nitride and tungsten nitride. The inner contact plugs 16 may have an integrated structure (see FIG. 4) formed with the first wiring patterns 15 thereunder in a damascene process, but an embodiment of the inventive concept is not limited thereto.

Active contact plugs 17a, connection contact structures 17b and gate contact plugs 17c may be provided in the first interlayer insulating layer IL. The active contact plugs 17a, the connection contact structures 17b and the gate contact plugs 17c may be substantially disposed at the same level on the basis of or relative to the first surface 1a of the first substrate 1. As used herein, a “level” of an element or component may refer to a distance of the element or component (or a sublayer of a layer structure including the element or component therein) from a reference layer or surface (e.g., the first surface 1a of the first substrate 1). As in a manufacturing method to be described later, the active contact plugs 17a, the connection contact structures 17b and the gate contact plugs 17c may be simultaneously formed of the same material.

The active contact plugs 17a and the gate contact plugs 17c may be provided in the sensing region APS and the optically black region OB. As illustrated, the active contact plugs 17a may be connected to the floating diffusion region FD, but an embodiment of the inventive concept is not limited thereto, and the active contact plugs 17a may be connected to active regions of the first substrate 1. The gate contact plugs 17c may be connected to the transfer gates TG, but an embodiment of the inventive concept is not limited thereto, and the gate contact plugs 17c may be connected to at least one of a gate electrode of a reset transistor, a gate electrode of a source follower transistor or a gate electrode of a selection transistor. The active contact plugs 17a and the gate contact plugs 17c may be connected to the first wiring patterns 15. The connection contact structures 17b may be provided in the pad region PAD. The connection contact structures 17b will be described in more detail later.

Light may not be incident from the optically black region OB into the substrate 1. The element isolation portion 13 may be disposed in the optically black region OB to separate a first black region UPO1 and a second black region UPO2. In the first black region UPO1, the photoelectric conversion portion PD may be disposed in the first substrate 1. In the second black region UPO2, the photoelectric conversion portion PD may not exist (i.e., may not be present) in the first substrate 1. The transfer gate TG and the floating diffusion region FD may be disposed in each of the first black region UPO1 and the second black region UPO2. The first black region UPO1 may provide a first reference charge by sensing a charge capable of being generated from the photoelectric conversion portion PD from which light is blocked. The first reference charge may be a relative reference value in calculating a charge generated by the photoelectric conversion portions PD in a pixel region. The second black region UPO2 may provide a second reference charge by sensing a charge capable of being generated when there is no photoelectric conversion portion PD. The second reference charge may be used as information for removing a process noise. A rear surface insulating layer 23 and an etch stop layer 26 may be sequentially provided on the second surface 1b of the first substrate 1. The rear surface insulating layer 23 and the etch stop layer 26 are described in more detail later.

In the optically black region OB, a first metal pattern 28 may be disposed on the etch stop layer 26. The first metal pattern 28 may be a portion of an optically black pattern that prevents light from being incident into the first substrate 1. The first metal pattern 28 may include at least one of a metal nitride layer such as a titanium nitride layer, a tantalum nitride layer or a tungsten nitride layer, a titanium layer or a tungsten layer. For example, the first metal pattern 28 may be a structure in which the titanium layer and the tungsten layer are sequentially stacked. According to other embodiments, the first metal pattern 28 may include a metal nitride layer and a metal layer. For example, the metal nitride layer may be a titanium nitride layer, and the metal layer may have a structure in which a titanium layer and a tungsten layer are sequentially stacked.

In the sensing region APS, a grid pattern 71 may be disposed on the etch stop layer 26. The grid pattern 71 may have a lattice structure in plan view. The grid pattern 71 may overlap the element isolation portion 13 in a region, but may not overlap the element isolation portion 13 in another region in consideration of an incident angle. Components or layers described with reference to “overlap” in a particular direction may be at least partially obstructed by one another when viewed along a line extending in the particular direction or in a plane perpendicular to the particular direction. The grid pattern 71 may include metal and/or an insulating material. For example, the grid pattern 71 may include a low refractive index layer including an organic material, or metal and a metal nitride such as tungsten, titanium and a nitride thereof. The low refractive index layer may have a refractive index lower than color filters CF1 and CF2. For example, the low refractive index layer may have a refractive index of about 1.3 or less.

In the sensing region APS, the color filters CF1 and CF2 may be disposed between the grid patterns 71. The color filters CF1 and CF2 may each have one different color among blue, green, and red. In the optically black region OB, a bulk color filter CFB may be disposed on the first metal pattern 28. For example, the bulk color filter CFB may include the same material as the blue color filter. The bulk color filter CFB may be a portion of the optically black pattern. A protective insulating layer 33 may be provided between the first metal pattern 28 and the bulk color filter CFB. Unlike what is illustrated, the protective insulating layer 33 may extend between the color filters CF1 and CF2 and the etch stop layer 26, but an embodiment of the inventive concept is not limited thereto. The protective insulating layer 33 may include an insulating material such as a high-dielectric material. For example, the protective insulating layer 33 may include aluminum oxide or hafnium oxide.

A conductive contact pattern CA may be disposed on the optically black region OB. The conductive contact pattern CA may be disposed in a first recess region RC1 formed on the optically black region OB. The conductive contact pattern CA may include a first buried conductive pattern 91 and a portion of the first metal pattern 28 extending into the first recess region RC1. The first buried conductive pattern 91 may include a metal material different from the first metal pattern 28. For example, the first buried conductive pattern 91 may include aluminum. The conductive contact pattern CA may be connected to the element isolation portion 13. For example, a voltage may be applied to the element isolation portion 13 through the conductive contact pattern CA. Alternatively, the conductive contact pattern CA and the conductive pattern 9 may not be provided.

A connection electrode VI and a pad contact pattern PA may be disposed on the pad region PAD. The connection electrode VI may penetrate the first substrate 1. The connection electrode VI may be disposed in a third recess region RC3. The third recess region RC3 may sequentially penetrate the etch stop layer 26, the rear surface insulating layer 23 and the first substrate 1. The pad contact pattern PA and the connection electrode VI may be spaced apart from each other horizontally, for example, in the first direction X.

The connection electrode VI may include a portion of a second metal pattern 29 extending into the third recess region RC3, a portion of the protective insulating layer 33 extending into the third recess region RC3 and a buried or burial pattern 84 with which a remaining region is filled. The first metal pattern 28 and the second metal pattern 29 may be separated between the optically black region OB and the pad region PAD.

The burial pattern 84 may include an insulating material. For example, the burial pattern 84 may include silicon oxide. A capping pattern 82 may be provided on the burial pattern 84. A lower surface of the capping pattern 82 may be convex downward, that is, protruding convexly toward the first substrate 1. An upper surface of the capping pattern 82 may be substantially flat. The capping pattern 82 may include insulating polymer such as a photoresist material.

The connection electrode VI may be connected, through the connection contact structure 17b, to a connection wiring pattern R1, which is closets or nearest to the first surface 1a of the first substrate 1, among the first wiring patterns 15 in the first interlayer insulating layer IL. For example, the first wiring patterns 15 may be disposed in a plurality of sublayers or levels at respective distances from the first surface 1a of the first substrate 1, and may include a connection wiring pattern R1 at or on a level that is nearest to the first surface 1a of the substrate 1, and wiring patterns R2 disposed farther from the first surface 1a than the connection wiring pattern R1. That is, the connection electrode VI may be electrically connected to a closest or lowermost wiring pattern (with reference to the first substrate 1) of the first chip CH1 through the connection contact structure 17b. Hereinafter, connection relation of the connection electrode VI, the connection contact structure 17b and the connection wiring pattern R1 will be described in more detail with reference to FIGS. 4 to 11.

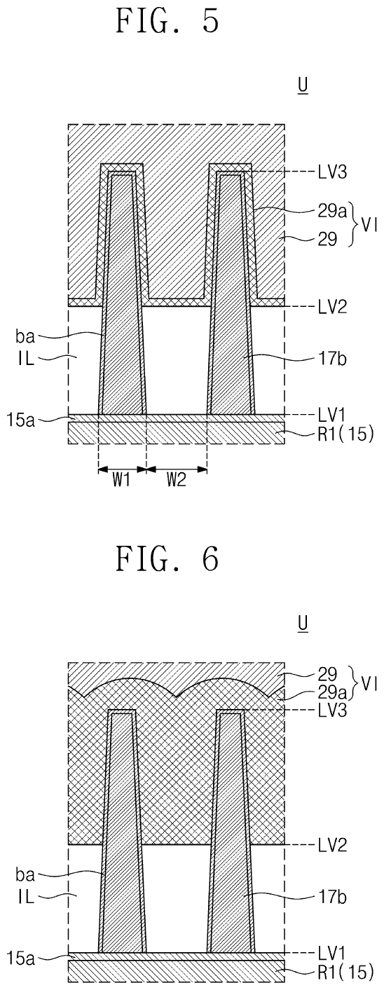

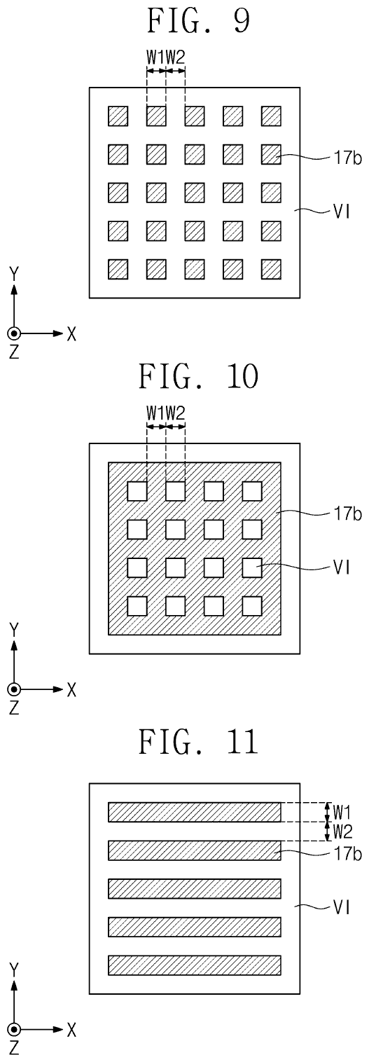

FIG. 4 is an enlarged view of region Q of FIG. 3. FIGS. 5 to 8 are enlarged views of region U of FIG. 4. FIGS. 9 to 11 are plan views of a connection contact structure and a connection electrode. As illustrated in FIGS. 4 to 8, the connection contact structure 17b may be provided on the connection wiring pattern R1 to connect the connection wiring pattern R1 and the connection electrode VI. For example, the connection contact structure 17b may be in contact with an upper surface of the connection wiring pattern R1. In the present specification, the wording, “being in contact” may include “direct contact” and “indirect contact”, and “indirect contact” includes that there is an impurity layer, or the like capable of being interposed on an oxide layer or an interface, between two components, but excludes that the two components are connected to each other through another component such as a line or contact plug. The connection wiring pattern R1 may include a first barrier layer 15a covering an upper surface thereof, and the connection contact structure 17b may be in contact with the first barrier layer 15a. A wiring insulating layer 19 may be provided in the first interlayer insulating layer IL, and the connection wiring pattern R1 may penetrate the wiring insulating layer 19. The wiring insulating layer 19 may include a silicon oxide layer.

The connection contact structure 17b may have a tapered shape from the connection wiring pattern R1 toward the first surface 1a of the first substrate 1. The connection contact structure 17b may include a part in which a width of a cross-section thereof continuously decreases in a direction towards or approaching to the first surface 1a. A width W1 of the connection contact structure 17b in a first level LV1, which is a level of a lower surface of the connection contact structure 17b may be greater than a width in a third level LV3, which is a level of an upper surface. Spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures.

In a cross-sectional view, the connection contact structure 17b may include a plurality of connection contact structures 17b spaced apart from each other, and the plurality of connection contact structures 17b may be connected to one connection electrode VI. FIGS. 3 and 4 illustrate that the connection contact structures 17b connected to one connection electrode VI are three or four, but the illustrated embodiments are by way of example only, and at least five connection contact structures 17b may be connected to one connection electrode VI in some embodiments. More generally, embodiments described herein may include fewer or more connection contact structures 17b than illustrated in the figures.

A distance W2 between the connection contact structures 17b may be greater than the width W1 of each of the connection contact structures 17b, in a direction parallel to the first surface 1a. For example, the distance W2 between the connection contact structures 17b may be about 1.2 times to about twice of the width W1 of each of the connection contact structures 17b. The connection contact structures 17b may be substantially spaced apart from each other with the same interval or pitch.

The connection contact structure 17b may substantially have the same cross-sectional shape as the active contact plug 17a described with reference to FIG. 3. For example, the width W1 of the lower surface of the connection contact structure 17b may be substantially the same as a width of a lower surface of the active contact plug 17a. In addition, a length in a third direction Z of the connection contact structure 17b may be substantially the same as a length in the third direction Z of the active contact plug 17a. The distance between the connection contact structures 17b may be smaller than a distance between the active contact plugs 17a. For example, the shortest distance between a pair of connection contact structures 17b may be smaller than the shortest distance between a pair of active contact plugs 17a.

The active contact plug 17a and the connection contact structure 17b may include a metal material different from the first wiring patterns 15, for example, at least one of tungsten, titanium or tantalum. The active contact plug 17a and the connection contact structure 17b may each include a barrier layer ba. For example, the barrier layer ba of the connection contact structure 17b may include at least one of titanium, tantalum, titanium nitride or tantalum nitride. The barrier layer ba of the connection contact structure 17b may not be provided between the connection contact structure 17b and the connection wiring pattern R1. Since the connection contact structure 17b is formed of a conductive material that is different from the conductive material of the connection wiring pattern R1 in a separate process, an interface (e.g., a visible interface) may be present between the connection contact structure 17b and the connection wiring pattern R1. In addition, the connection contact structure 17b may be formed of a material having greater etching resistance than the connection wiring pattern R1 in an etching process for forming a third recess region RC3 to be described later to reduce or minimize damage caused by the etching process.

As illustrated in FIGS. 4 to 8, at least an upper portion of the connection contact structure 17b may be inserted or may penetrate or otherwise extend into a lower portion of the connection electrode VI. For example, a second level LV2, which is a level of a lower surface of the connection electrode VI may be about 30% to about 80% of a height of the connection contact structure 17b (a length in the third direction Z). A lower sidewall of the connection contact structure 17b may not be covered by the connection electrode VI, and may be in contact with the first interlayer insulating layer IL. That is, the first interlayer insulating layer IL may extend between the connection wiring pattern R1 and the connection electrode VI. In this case, the first interlayer insulating layer IL may fill a space between a plurality of connection contact structures 17b.

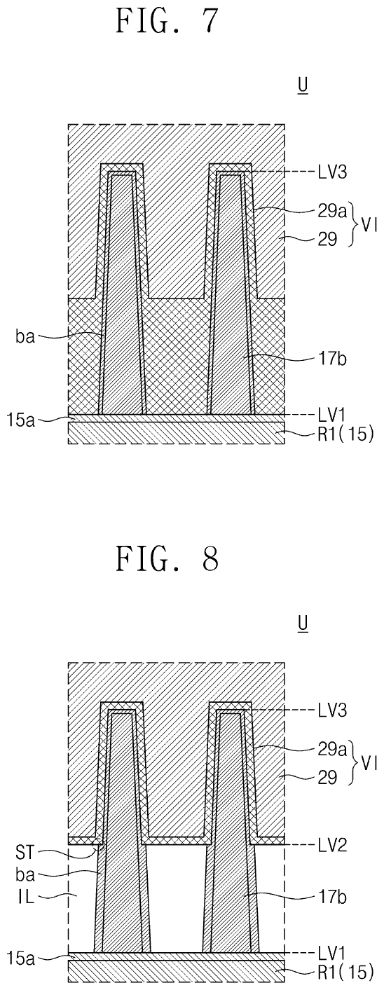

According to embodiments, as illustrated in FIG. 7, a lower surface of the connection electrode VI may extend to the first level LV1, which is a level of a lower surface of the connection contact structure 17b, and at least a portion of the lower surface may be in contact with the connection wiring pattern R1. As illustrated in FIG. 8, the connection contact structure 17b may include a step structure ST in which a width thereof discontinuously changes at the second level LV2, which is the level of the lower surface of the connection electrode VI. The step structure ST may be caused by a shape left on the sidewall of the connection contact structure 17b by etching for forming the third recess region RC3.

The second metal pattern 29 that constitutes the connection electrode VI may include the same material as the connection contact structure 17b. For example, the second metal pattern 29 may include at least one of tungsten, titanium, or tantalum. The connection electrode VI may further include a barrier layer 29a on a surface thereof. For example, the barrier layer 29a of the connection electrode VI may include at least one of titanium, tantalum, titanium nitride or tantalum nitride. As in FIGS. 5, 7, and 8, the barrier layer 29a of the connection electrode VI may extend along upper portions of the connection contact structures 17b, and portions therebetween may be filled with the barrier layer 29a of the connection electrode VI, and the remaining portions between the upper portions of the connection contact structures 17b may be filled with second metal pattern 29. Alternatively, as illustrated in FIG. 6, spaces between the upper portions of the connection contact structures 17b may be completely filled with the barrier layer 29a of the connection electrode VI.

FIGS. 9 to 11 are plan views of a connection contact structure and a connection electrode. The plan views in FIGS. 9 to 11 are plan views on the basis of the first level LV1, which is the level of the lower surface of the connection contact structure 17b.

Referring to FIG. 9, the connection contact structures 17b according to the present embodiment may have a shape of a contact plug of which the widths in the first direction X and the second direction Y are substantially the same as each other in plan view. The connection contact structures 17b may be disposed spaced apart from each other in the first direction X and the second direction Y. In order to simplify description, a plan view shape (also referred to as a planar shape) of the connection contact structure 17b is illustrated as a tetragon, but an embodiment of the inventive concept is not limited thereto, and the planar shape of the connection contact structure 17b may be a circle or a polygon. The connection contact structures 17b according to the present embodiment may have the same planar shape as the active contact plugs 17a. The connection electrode VI may extend between the connection contact structures 17b, and may have a lattice shape at the first level LV1.

Referring to FIG. 10, the connection contact structure 17b according to the present embodiment may have, in plan view, a shape of a lattice extending in the first direction X and second direction Y, and including parts connected to each other. A lower portion of the connection electrode VI may include a part surrounding an outer peripheral surface of the connection contact structure 17b having a shape of a lattice and parts having a shape of a plurality of plugs penetrating the lattice.

Referring to FIG. 11, the connection contact structures 17b according to the present embodiment may have a shape of bars extending in the first direction X and spaced apart from each other in the second direction Y. Alternatively, the connection contact structures 17b may extend in the second direction Y and may be spaced apart from each other in the first direction X.

Referring back to FIGS. 2 to 4, in the pad region PAD, a second element isolation layer 6 may be disposed adjacent to the first surface 1a of the first substrate 1. The second element isolation layer 6 may include a silicon oxide layer inserted from the first surface 1a of the first substrate 1 into an inside thereof like the first element isolation layer 5 provided to the sensing region APS. For example, the second element isolation layer 6 may include a silicon nitride layer 8 interposed between silicon oxide layers. As illustrated in FIGS. 1 and 2, the second element isolation layer 6 may be disposed adjacent to each of the pad contact patterns PA spaced apart from each other along the first direction X or the second direction Y, and the second element isolation layers 6 may be separated from each other. That is, one second element isolation layer 6 may be disposed adjacent to each of the pad contact patterns PA, but an embodiment of the inventive concept is not limited thereto, and the one second element isolation layer 6 may be matched with a plurality of pad contact patterns PA.

The second element isolation layer 6 may have a greater width t1 in the first direction X and/or a width t2 in the second direction Y than the first element isolation layer 5 (see FIG. 2). For example, the second element isolation layer 6 may have a greater area with reference to the first surface 1a of the first substrate 1 than the first element isolation layer 5. The lower portion of the connection electrode VI may penetrate the second element isolation layer 6.

The pad contact pattern PA may be provided in the second recess region RC2. The pad contact pattern PA may include a second buried conductive pattern 92 and a portion of the second metal pattern 29 extending into the second recess region RC2. The second buried conductive pattern 92 may include a metal material different from the second metal pattern 29. For example, the second buried conductive pattern 92 may include aluminum. A voltage may be applied to the transistors TR of the second chip CH2 through the pad contact pattern PA, the connection electrode VI, the first wiring patterns 15 and the second wiring patterns 112. For example, the pad contact pattern PA may be connected to a circuit outside a chip (also referred to as an external circuit) in or using wire-bonding, or the like.

The sensing region APS may be covered by a micro-lens layer ML. The micro-lens layer ML may be provided on the optically black region OB and the pad region PAD. The micro-lens layer ML may not cover the pad contact pattern PA. The micro-lens layer ML may have a shape of a convex lens on each light receiving region UP of the sensing region APS. The micro-lens layer ML may have a flat upper surface on the optically black region OB.

The rear surface insulating layer 23 may be provided on the second surface 1b of the first substrate 1. The rear surface insulating layer 23 may be a bottom antireflective coating (BARC) layer. For example, the rear surface insulating layer 23 may include a fixed charge layer, a refractive index control layer, and a capping layer sequentially provided on the first substrate 1. The fixed charge layer may be composed of a metal oxide layer or a metal fluoride layer including an amount of oxygen or fluorine less than a stoichiometric ratio thereof. Accordingly, the fixed charge layer may have a negative fixed charge. The fixed charge layer may include metal oxide or metal fluoride including at least one metal of hafnium, zirconium, aluminum, tantalum, titanium, yttrium, or lanthanoid. For example, the fixed charge layer may be an aluminum oxide layer. Hole accumulation may occur around the fixed charge layer. Generation of a dark current and a white spot of the image sensor may be effectively reduced by the fixed charge layer.

The refractive index control layer may control a path of light such that the light incident onto the second surface 1b of the first substrate 1 may smoothly reach the photoelectric conversion portion PD. The refractive index control layer may include a metal oxide layer. For example, the refractive index control layer may include at least one of a titanium oxide layer, a tantalum oxide layer, or a hafnium oxide layer. The capping layer may include a layer having a lower dielectric constant than the refractive index control layer and the fixed charge layer. For example, the capping layer may include silicon oxide.

The first chip CH1 and the second chip CH2 may be electrically connected to each other through bonding pads provided to each chip. The first chip CH1 may include first bonding pads 41 exposed to a lower surface of the first interlayer insulating layer IL, and the second chip CH2 may include second bonding pads 141 exposed by an upper surface of the second interlayer insulating layer 110. The term “exposed,” may be used to describe relationships between elements and/or certain intermediate processes in fabricating a completed semiconductor device, but may not necessarily require exposure of the particular region, layer, structure or other element in the context of the completed device. The first bonding pads 41 and the second bonding pads 141 may include at least one of copper, tungsten, aluminum, tungsten nitride, tantalum nitride or titanium nitride.

The first bonding pads 41 and the second bonding pads 141 may be directly electrically connected to each other in an intermetallic hybrid bonding manner. The phrase “hybrid bonding” refers to a bonding in which two components including the same type of material fuse at an interface thereof. For example, when first and second bonding pads 41 and 141 include copper (Cu), the first and second bonding pads 41 and 141 may be physically and electrically connected to each other by a copper (Cu)-copper (Cu) bonding. In addition, the first interlayer insulating layer IL of the first chip CH1 and the second interlayer insulating layer 110 of the second chip CH2 may be bonded to each other by a dielectric-dielectric bonding. Unlike what is illustrated, the first chip CH1 and the second chip CH2 may be electrically connected to each other by a penetration electrode penetrating the first chip CH1, and connected to the first wiring pattern 15 and the second wiring pattern 112 in common.

According to embodiments of the inventive concept, the connection electrode VI (which is electrically connected to the pad contact pattern PA) may be electrically connected to the connection wiring pattern R1 by the connection contact structure 17b provided at the same level as the active contact plugs 17a, e.g., at a same level of the first interlayer insulating layer IL relative to the first surface 1a of the first substrate 1. Accordingly, damage to the connection wiring pattern R1 may be reduced or minimized during formation of a recess region for the connection electrode VI. In addition, the connection contact structure 17b may include a different material having greater etching resistance than the connection wiring pattern R1 in an etching process for forming the third recess region RC3 to reduce or minimize damage caused by the etching process.

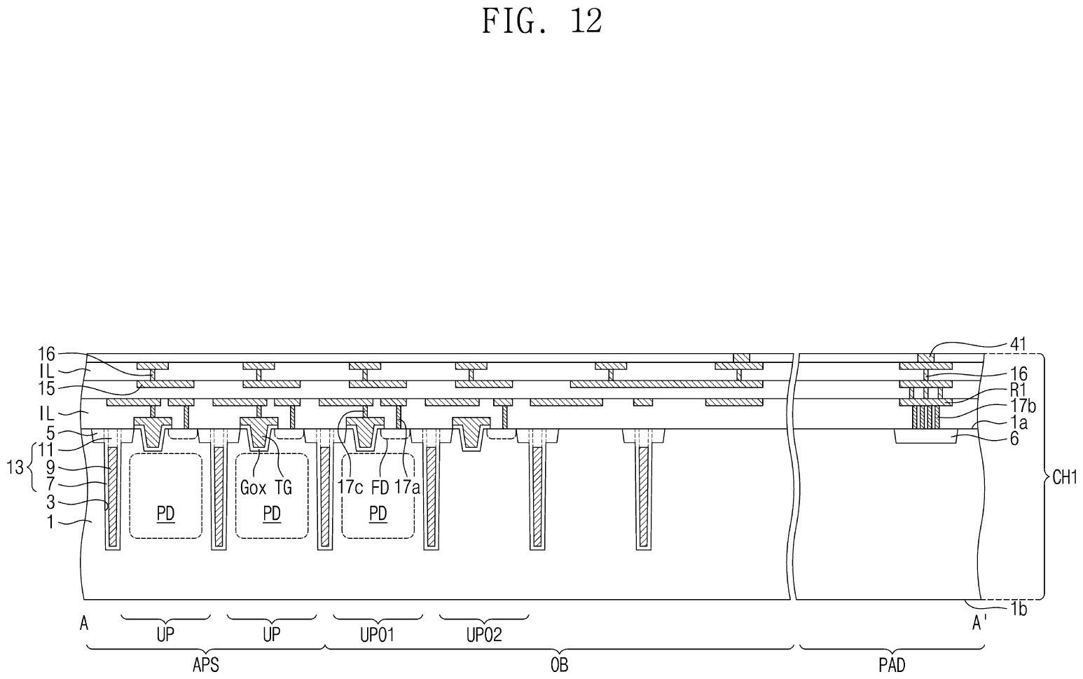

FIGS. 12 to 17 are diagrams sequentially illustrating a method for manufacturing an image sensor according to embodiments of the inventive concept, and are cross-sectional views taken along line A-A′ of FIG. 1.

Referring to FIG. 12, the first chip CH1 is manufactured. The photoelectric conversion portions PD are formed by performing an ion-implantation process or the like to the first substrate 1 including the sensing region APS, the optically black region OB and the pad region PAD. The first element isolation layer 5 and the second element isolation layer 6 may be formed on the first surface 1a of the first substrate 1. The first element isolation layer 5 may be formed on the sensing region APS and the optically black region OB, and the second element isolation layer 6 may be formed on the pad region PAD. The first element isolation layer 5 and the second element isolation layer 6 may be simultaneously formed in a shallow trench isolation (STI) process. The trenches 3 are formed by partially etching the first element isolation layer 5 and the first substrate 1. The trenches 3 may limit the light receiving regions UP and the black regions UPO1 and UPO2 in the sensing region APS and the optically black region OB. The trenches 3 may not be formed in the pad region PAD.

Each conductive pattern 9 is formed in the trenches 3 by conformally forming the isolation insulating layer 7 on the whole surface of the first surface 1a of the first substrate 1, filling the trenches 3 with a conductive material, and performing an etch-back process. The first surface 1a may be exposed by forming the buried insulating patterns 11 on the conductive patterns 9 and removing the isolation insulating layer 7 on the first surface 1a. As a result, the element isolation portion 13 including the conductive patterns 9, the isolation insulating layer 7 and the buried insulating patterns 11 may be formed.

The gate insulating layer Gox, the transfer gate TG, the floating diffusion region FD and a portion of the first interlayer insulating layer IL may be formed in the first surface 1a of the first substrate 1. The active contact plugs 17a, the connection contact structure 17b and the gate contact plugs 17c may be formed. The active contact plugs 17a, the connection contact structure 17b and the gate contact plugs 17c may be simultaneously formed of the same material through a damascene process. The connection contact structure 17b may be connected to the second element isolation layer 6, but an embodiment of the inventive concept is not limited thereto.

The connection contact structure 17b may be formed so as to have the substantially same width as the active contact plugs 17a. As a result, a loading effect, such as dishing, capable of being generated by sizes of the active contact plugs 17a and the connection contact structure 17b, especially a difference of widths may be reduced or prevented. Thereafter, the remaining portion of the first interlayer insulating layer IL, the first wiring patterns 15 and the inner contact plugs 16 may be formed. For example, the first wiring patterns 15 may include copper. The inner contact plugs 16 may connect the first wiring patterns 15. The first bonding pads 41 may be formed on the first interlayer insulating layer IL. For example, the first bonding pads 41 may be formed of at least one of copper, tungsten, aluminum, tungsten nitride, tantalum nitride or titanium nitride.

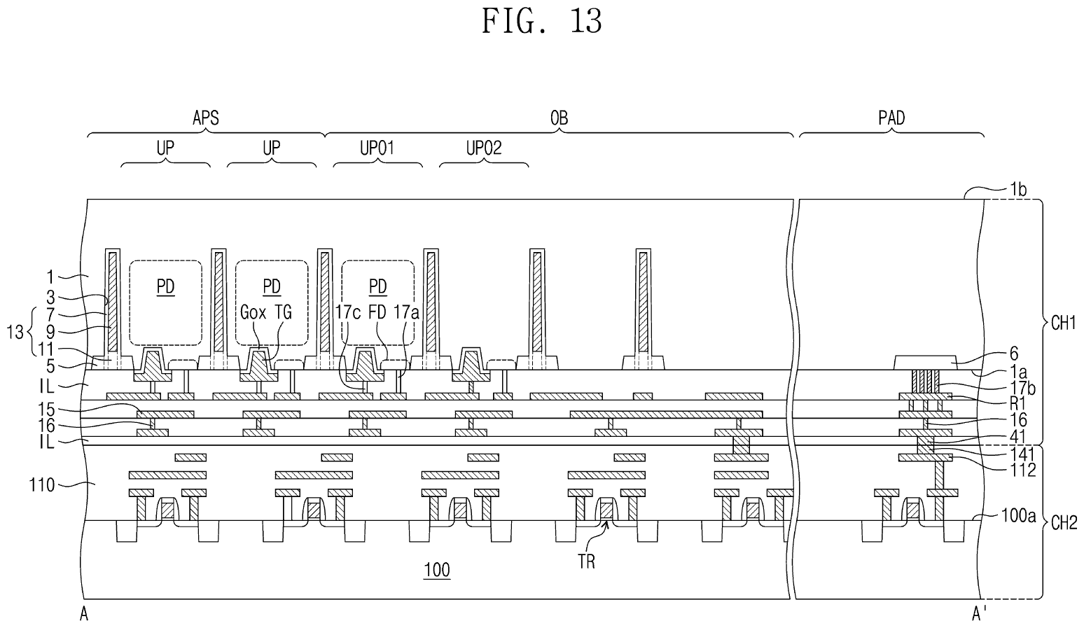

Referring to FIG. 13, the second chip CH2 may be prepared, and the first chip CH1 may be turned over to attach the second chip CH2. After the first interlayer insulating layer IL is located so as to be in contact with the second interlayer insulating layer 110, the first chip CH1 may be bonded onto the second chip CH2 by performing a thermocompression process, or the like. The second bonding pads 141 may be provided on the second chip CH2, and the first bonding pads 41 and the second bonding pads 141 may be melted to be bonded to each other. In addition, the first interlayer insulating layer IL of the first chip CH1 and the second interlayer insulating layer 110 of the second chip CH2 may be bonded to each other while being in contact with each other.

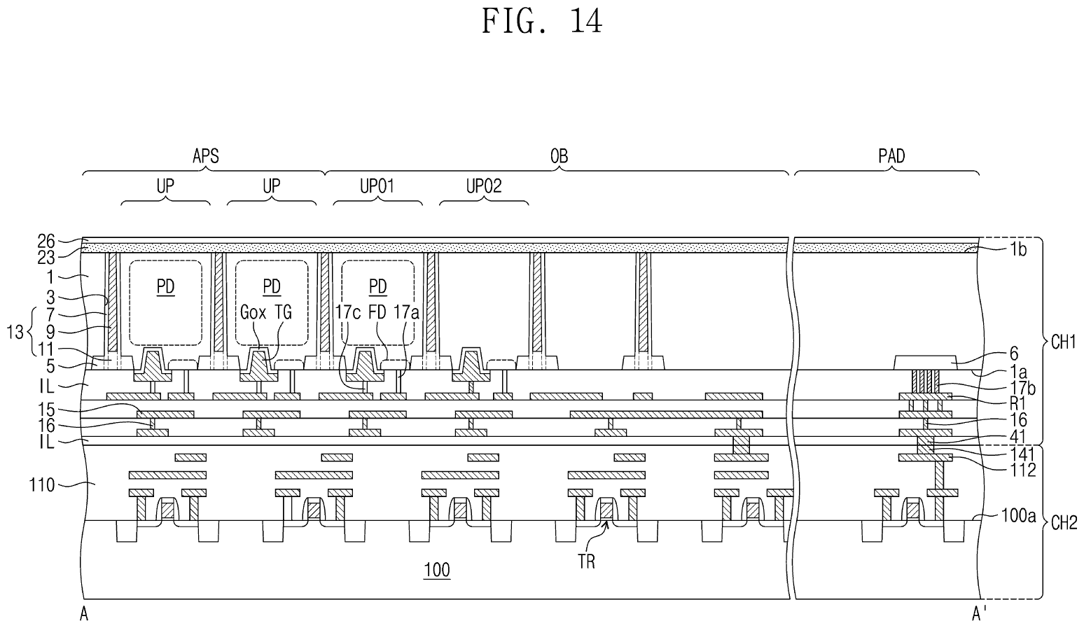

Referring to FIG. 14, a thickness of the first substrate 1 may be reduced by performing a grinding process on the second surface 1b of the first substrate 1. In this case, the conductive pattern 9 of the element isolation portion 13 may be exposed. The rear surface insulating layer 23 may be deposited on the second surface 1b of the first substrate 1. The etch stop layer 26 may be formed on the rear surface insulating layer 23. For example, the etch stop layer 26 may be formed of a hafnium oxide layer.

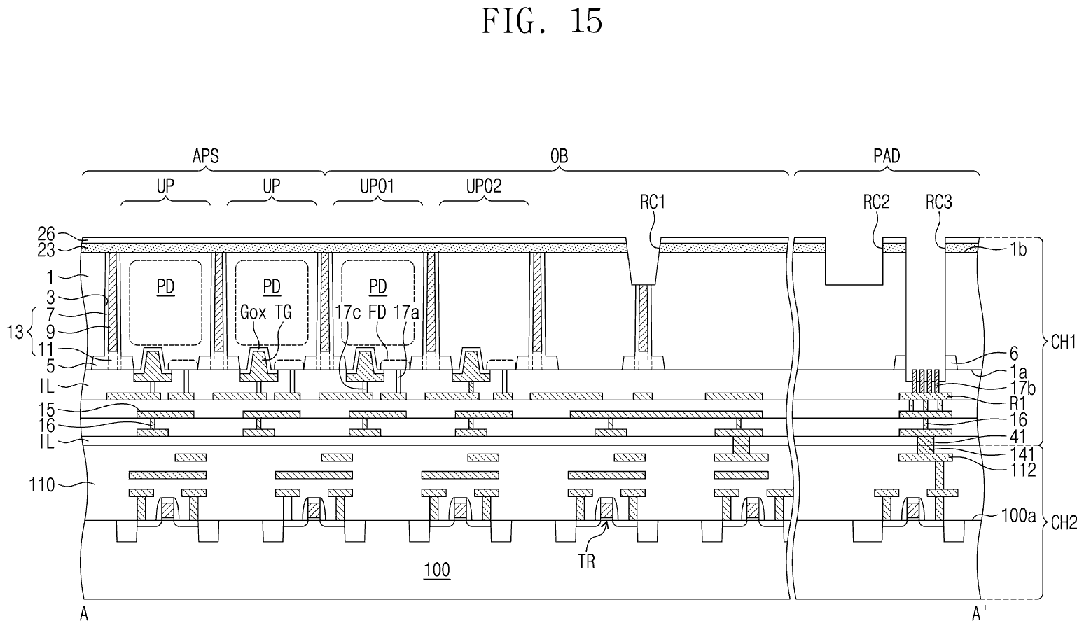

Referring to FIG. 15, the first recess region RC1 may be formed in the optically black region OB, and the second recess region RC2 and the third recess region RC3 may be formed in the pad region PAD. Forming the first to third recess regions RC1, RC2 and RC3 may include at least one dry etching process. For example, the first recess region RC1 and the second recess region RC2 may be formed together, and the third recess region RC3 may be separately formed, but unlike this, at least some etching process may be shared. The first recess region RC1 may expose the conductive pattern 9. Hereinafter, forming the third recess region RC3 will be described in more detail.

After a mask pattern for forming the third recess region RC3 is formed on the etch stop layer 26, the etch stop layer 26, the rear surface insulating layer 23, the first substrate 1 and the second element isolation layer 6 may be sequentially etched by performing an etching process. The second element isolation layer 6 may include a material different from the first substrate 1 to have etching characteristics different from the first substrate 1, and thus the second element isolation layer 6 may be used as an etch stop layer in the present etching step. The present etching process may be performed until an upper portion of the connection contact structure 17b is exposed. Thereafter, the mask pattern may be removed by performing an ashing process and a strip process. The third recess region RC3 may not expose the connection wiring pattern R1. That is, a depth of extension of the third recess region RC3 into the first substrate 1 (as measured from the second surface 1b) may be shallower than a depth of a recess region that extends completely through the first interlayer insulating layer IL to expose the connection wiring pattern R1.

When the connection wiring pattern R1 is exposed during formation of the third recess region RC3, the connection wiring pattern R1 may be damaged or partially lost. For example, when the connection wiring pattern R1 is formed of copper, a copper oxide layer (which may be formed by an upper surface of the connection wiring pattern R1 being partially oxidized) may be lost together in a process of removing the mask pattern, including the strip process. As a result, there may be a limitation in an electrical connection between the connection wiring pattern R1 and the connection electrode VI, that is, the electrical connection may be compromised. According to embodiments of the inventive concept, the connection contact structure 17b may be formed of a conductive material having greater etching resistance than the connection wiring pattern R1 in an etching process of the third recess region RC3. According to embodiments of the inventive concept, the connection wiring pattern R1 and the connection electrode VI may be connected to each other through the connection contact structure 17b, and thus yield deterioration caused by the limitation (whereby the electrical connection between the connection wiring pattern R1 and the connection electrode VI may be compromised during formation of the third recess region RC3) may be improved. In addition, since the third recess region RC3 has a smaller or shallower depth than a recess region completely penetrating the first interlayer insulating layer IL and also exposing the second wiring patterns 112 of the second chip CH2, the etching process may be easier.

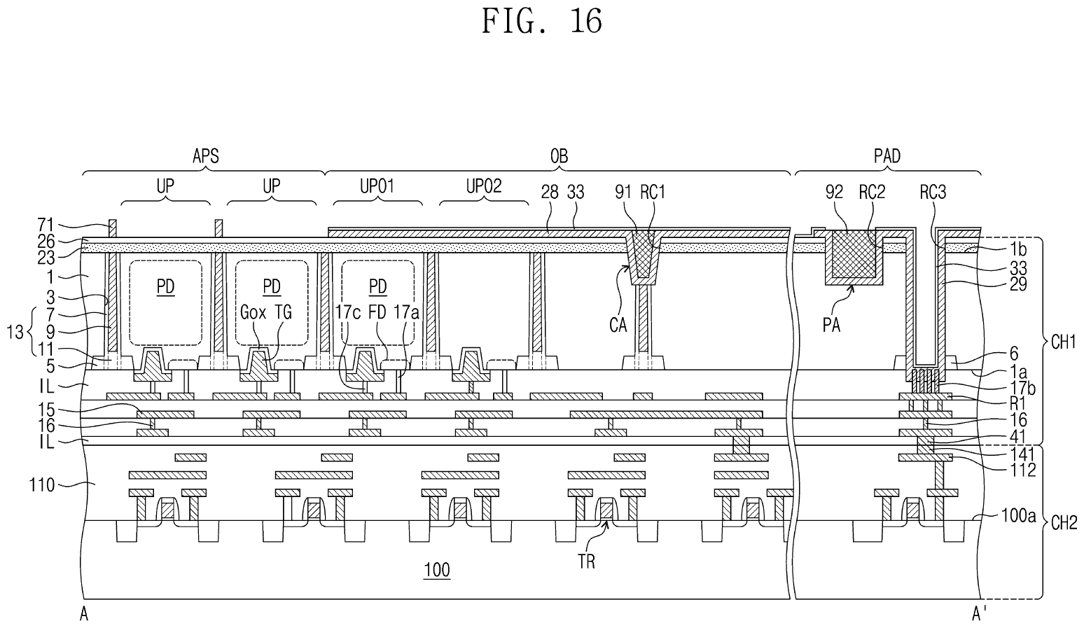

Referring to FIG. 16, the first metal pattern 28 and the second metal pattern 29 may be formed by conformally depositing and patterning a metal layer. For example, forming the first metal pattern 28 and the second metal pattern 29 may include sequentially depositing a titanium nitride layer, a titanium layer and a tungsten layer. The grid pattern 71 may be formed in the sensing region APS. Forming the grid pattern 71 may include a patterning process by using the etch stop layer 26.

The first buried conductive pattern 91 that fills the first recess region RC1 and the second buried conductive pattern 92 that fills the second recess region RC2 may be formed. Accordingly, forming the conductive contact pattern CA and the pad contact pattern PA is completed. The first buried conductive pattern 91 and the second buried conductive pattern 92 may be formed of a metal material different from the first metal pattern 28. For example, the first buried conductive pattern 91 and the second buried conductive pattern 92 may be formed of aluminum. For example, the first buried conductive pattern 91 and the second buried conductive pattern 92 may be formed in a sputtering process. Before the first buried conductive pattern 91 and the second buried conductive pattern 92 are formed, the third recess region RC3 may be filled with a separate insulating layer so that a conductive material may not be formed therein. Thereafter, the insulating layer may be removed.

The protective insulating layer 33 may be conformally formed on the whole surface (i.e., up to an entirety) of the second surface 1b of the first substrate 1. The protective insulating layer 33 may extend into the third recess region RC3. The protective insulating layer 33 may be formed of aluminum oxide or hafnium oxide. The second buried conductive pattern 92 may be exposed by partially removing the protective insulating layer 33. Exposing the second buried conductive pattern 92 may be performed in the present step, but unlike this, may be performed after a step of forming the micro-lens layer ML to be described later.

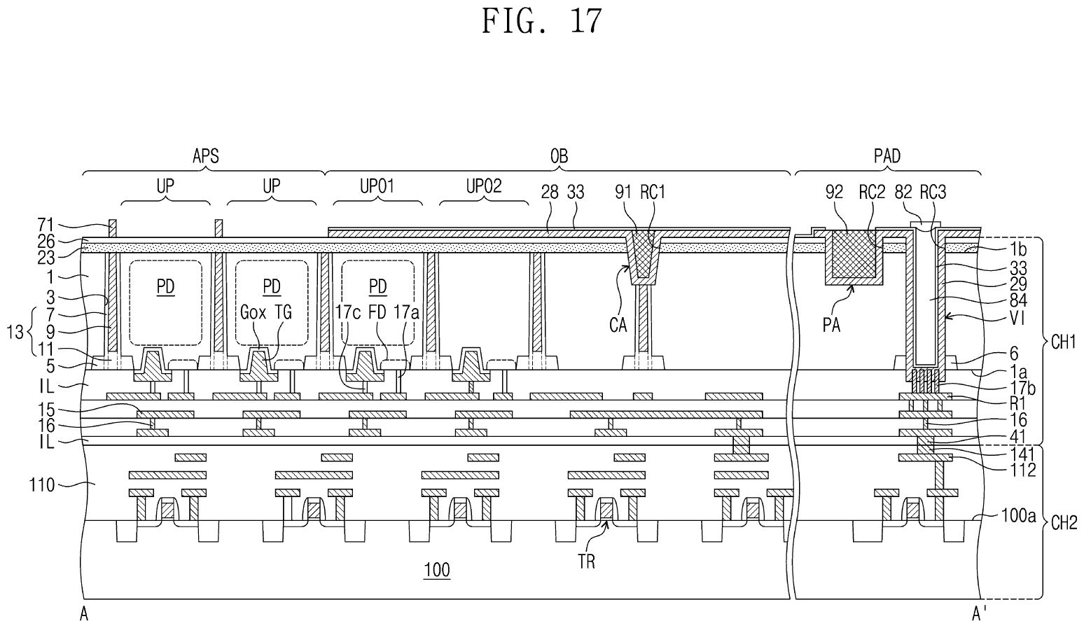

Referring to FIG. 17, the burial pattern 84 that fills the third recess region RC3 may be formed. For example, after an insulating layer, including silicon oxide or carbon, that fills the third recess region RC3 is formed, a patterning process may be performed. The capping pattern 82 may be formed on the burial pattern 84. For example, the capping pattern 82 may be formed of photoresist. Accordingly, forming the connection electrode VI is completed.

Referring back to FIG. 3, the color filters CF1 and CF2 and the bulk color filter CFB may be formed. The bulk color filter CFB may be formed together when the blue color filter is formed. The micro-lens layer ML may be formed on the color filters CF1 and CF2 and the bulk color filter CFB. The micro-lens layer ML may be formed in the sensing region APS and the optically black region OB. A portion of the protective insulating layer 33 covering the second buried conductive pattern 92 and a portion of the micro-lens layer ML may be removed.

According to embodiments of the inventive concept, since the connection electrode VI and the connection wiring pattern R1 are connected through the connection contact structure 17b that is exposed by a recess region RC3 having a shallower depth than the connection wiring pattern R1, damage to the connection wiring pattern R1 may be prevented during formation of a recess region RC3 for the connection electrode VI, and thus yield deterioration may be improved. In addition, since the connection contact structure 17b is formed together with (i.e., in the same fabrication operation(s) as) the active contact plugs 17a, a damage to the connection wiring pattern may be improved without a separate additional process.

FIG. 18 is a cross-sectional view of an image sensor according to embodiments of the inventive concept, and is a cross-sectional view taken along line A-A′ of FIG. 1. In order to simplify description, description of duplicate components may be omitted.

Referring to FIG. 18, the image sensor according to the present embodiment may have a structure in which a third chip CH3 is added between the first chip CH1 and the second chip CH2 of the image sensor described with reference to FIG. 3. The third chip CH3 may include a third substrate 200, a plurality of transistors TR disposed on a first surface 200a of the third substrate 200, a third interlayer insulating layer 210 covering the third substrate 200, and third wiring patterns 212 disposed in the third interlayer insulating layer 210. The transistors TR of the third chip CH3 may include a reset transistor, a source follower transistor and a selection transistor.

The third substrate 200 may be a portion of a silicon single-crystalline substrate, or a portion of a silicon-on-insulator (SOI) substrate. The third chip CH3 may include third bonding pads 241 exposed by an upper surface of the third interlayer insulating layer 210. The third bonding pads 241 may be connected to the first bonding pads 41. The third chip CH3 may include a fourth interlayer insulating layer 211 on a second surface 200b, which is an opposite surface of the first surface 200a. Fourth bonding pads 242 may be provided in the fourth interlayer insulating layer 211, and may be connected to the second bonding pads 141 of the second chip CH2.

In the present specification, a concept of individual chips may be defined as stack structures formed from different semiconductor wafers. A boundary of the individual chips may not be clearly inspected (e.g., may not be visible) depending on a bonding shape of or a bonding material between the chips, but the stack structure is not also excluded from the concept of the individual chips formed from the different semiconductor wafers.

In an image sensor according to the inventive concept, a recess region for a connection electrode is formed to a depth that is shallower than a depth of an underlying connection wiring pattern, such that damage to the connection wiring pattern may be prevented to improve yield reduction. In addition, since a connection contact structure is formed together with (i.e., in the same fabrication operation(s) as) active contact plugs, damage to the connection wiring pattern may be improved without a separate additional process.

Although the embodiments of the present invention have been described, it is understood that the present invention should not be limited to these embodiments but various changes and modifications can be made by one ordinary skilled in the art within the scope of the present invention as hereinafter claimed. Therefore, it should be understood that the embodiments described above are exemplary in all respects and are not intended to be limiting. In addition to the individual embodiments described, embodiments of the present invention may include embodiments in which configurations of the individual embodiments are combined, exchanged, and modified.

What is claimed is:

1. An image sensor comprising:
a first chip comprising a first substrate including a sensing region and a pad region and opposing first and second surfaces, a first interlayer insulating layer on the first surface of the first substrate and having first wiring patterns therein, and color filters on the second surface of the first substrate; and
a second chip on the first surface of the first substrate,
wherein the first chip comprises, in the pad region, a pad contact pattern, a connection electrode electrically connected to the pad contact pattern, and a connection contact structure electrically connected to the connection electrode, and
wherein the first wiring patterns comprise a connection wiring pattern that is nearest to the first surface, and the connection contact structure is electrically connected to the connection wiring pattern.

2. The image sensor of claim 1, wherein the connection contact structure is tapered from the connection wiring pattern toward the first surface.

3. The image sensor of claim 1, wherein the first chip further comprises:
photoelectric conversion portions in the first substrate in the sensing region;
transistors between the photoelectric conversion portions and the first interlayer insulating layer; and
active contact plugs in the first interlayer insulating layer and electrically connected to active regions of the transistors,
wherein the connection contact structure is at a same level of the first interlayer insulating layer as the active contact plugs relative to the first surface of the first substrate.

4. The image sensor of claim 3, wherein the connection contact structure and the active contact plugs comprise a first conductive material that is different from a second conductive material of the connection wiring pattern.

5. The image sensor of claim 1, wherein at least an upper portion of the connection contact structure penetrates into a lower portion of the connection electrode.

6. The image sensor of claim 5, wherein the connection contact structure comprises a plurality of connection contact structures,
wherein the connection electrode comprises a barrier layer, and
wherein the barrier layer extends between the plurality of connection contact structures.

7. The image sensor of claim 6, wherein the barrier layer extends between sidewalls of the connection contact structures.

8. The image sensor of claim 6, wherein the connection contact structure comprises a plurality of connection contact structures, and
wherein the first interlayer insulating layer extends between the connection wiring pattern and the connection electrode, and extends between sidewalls of the plurality of connection contact structures.

9. The image sensor of claim 1, wherein the first chip further comprises:
a first element isolation layer in the sensing region of the first substrate; and
a second element isolation layer in the pad region of the first substrate,
wherein the connection electrode penetrates the second element isolation layer.

10. The image sensor of claim 9, wherein the pad contact pattern comprises a plurality of pad contact patterns,
wherein the second element isolation layer comprises a plurality of second element isolation layers, and
wherein the plurality of second element isolation layers are adjacent to respective ones of the plurality of pad contact patterns, and are laterally spaced apart from each other.

11. The image sensor of claim 1, wherein the connection contact structure comprises a plurality of connection contact structures, and
wherein, in a direction parallel to the first surface of the first substrate, respective distances between the plurality of connection contact structures that are electrically connected to the connection electrode is greater than a width of each of the plurality of connection contact structures.

12. The image sensor of claim 1, wherein the connection contact structure comprises a plurality of connection contact structures, and
wherein the plurality of connection contact structures are spaced apart from each other in a first direction parallel to the first surface of the first substrate and in a second direction intersecting the first direction.

13. The image sensor of claim 1, wherein the connection contact structure has a shape of a lattice extending in a first direction parallel to the first surface of the first substrate and in a second direction intersecting the first direction.

14. The image sensor of claim 1, wherein the connection contact structure comprises a plurality of connection contact structures, and
wherein the plurality of connection contact structures have respective bar shapes extending in a first direction parallel to the first surface of the first substrate and spaced apart from each other in a second direction intersecting the first direction.

15. An image sensor comprising:
a first chip comprising a first substrate including a sensing region and a pad region and opposing first and second surfaces, a first interlayer insulating layer on the first surface of the first substrate and having first wiring patterns therein, and color filters on the second surface of the first substrate; and
a second chip on the first surface of the first substrate,
wherein the first chip comprises:
in the pad region, a pad contact pattern, a connection electrode electrically connected to the pad contact pattern, and a connection contact structure electrically connected to the connection electrode; and
in the sensing region, active contact plugs electrically connected to active regions of the first substrate, and
wherein the active contact plugs and the connection contact structure are at a same level of the first interlayer insulating layer relative to the first surface, and have respective shapes that are tapered toward the first surface.

16. The image sensor of claim 15, wherein the first wiring patterns comprise a connection wiring pattern that is nearest to the first surface, wherein the connection contact structure is electrically connected to the connection wiring pattern, and
wherein the connection contact structure and the active contact plugs comprise a first conductive material that is different from a second conductive material of the connection wiring pattern.

17. The image sensor of claim 15, wherein at least an upper portion of the connection contact structure penetrates into a lower portion of the connection electrode.

18. The image sensor of claim 15, wherein the first chip further comprises a first element isolation layer in the sensing region of the first substrate and a second element isolation layer in the pad region of the first substrate, and
wherein the connection electrode penetrates the second element isolation layer.

19. The image sensor of claim 15, wherein the connection contact structure comprises a plurality of connection contact structures, and
wherein, in a direction parallel to the first surface of the first substrate, respective distances between the plurality of connection contact structures that are electrically connected to the connection electrode is greater than a width of each of the plurality of connection contact structures.

20. An image sensor comprising:
a first chip comprising a sensing region, a pad region, and an optically black region between the sensing region and the pad region; and
a second chip on one surface of the first chip, the second chip comprising circuits configured for driving the first chip,
wherein the first chip comprises:
a first substrate having opposing first and second surfaces;
transfer gates on the first surface of the first substrate;
an element isolation portion in the first substrate;
a rear surface insulating layer on the second surface of the first substrate;
photoelectric conversion portions laterally spaced apart from each other with the element isolation portion therebetween;
a first interlayer insulating layer between the first substrate and the second chip; and
first wiring patterns in the first interlayer insulating layer,
wherein the second chip comprises a second substrate, a second interlayer insulating layer, and second wiring patterns in the second interlayer insulating layer on the second substrate,
wherein the first chip further comprises, in the pad region, a pad contact pattern, a connection electrode electrically connected to the pad contact pattern, and a connection contact structure electrically connected to the connection electrode, and
wherein the first wiring patterns comprise a connection wiring pattern that is nearest to the first surface, and the connection contact structure is electrically connected to the connection wiring pattern.
